(19) United States
(12) Patent Application Publication
(10) Pub. No.: US 2026/0196168 A1
(43) Pub. Date: Jul. 9, 2026

(54) PIXEL AND ELECTRONIC DEVICE INCLUDING THE PIXEL

(71) Applicants: Samsung Display Co., LTD., Yongin-si (KR); Konkuk University Industrial Cooperation Corp., Seoul (KR)

(72) Inventors: HYUNJOON KIM, Yongin-si (KR); YIKYOUNG YOU, Seoul (KR); KEECHAN PARK, Seoul (KR); DANWON LIM, Yongin-si (KR); JAEHYUNG CHO, Yongin-si (KR)

(21) Appl. No.: 19/388,060

(22) Filed: Nov. 13, 2025

(30) Foreign Application Priority Data
Jan. 8, 2025 (KR) 10-2025-0002663

(51) Int. Cl. G09G 3/3225; G09G 3/32

(52) U.S. Cl. CPC G09G 3/3225; G09G 3/32; G09G 2300/043; G09G 2310/08

(57) ABSTRACT

A pixel of an electronic device includes a light emitting element connected between a first voltage line and a first node, a first transistor including a first electrode connected to a second node, a second electrode connected to a third node, a gate electrode connected to a fourth node, and a bottom gate electrode, a second transistor connected between a first voltage line and the first node, a third transistor connected between the first node and the second node, a fourth transistor connected between the second node and the fourth node, a fifth transistor connected between a first data line and a fifth node, a sixth transistor connected between a second data line, a seventh transistor connected between the third node and a second voltage line, an eighth transistor connected between the fifth node and the second voltage line, a first capacitor and a second capacitor.

This application claims priority to Korean Patent Application No. 10-2025-0002663, filed on January 08, 2025, and all the benefits accruing therefrom under 35 U.S.C. §119, the content of which in its entirety is herein incorporated by reference.

### BACKGROUND

Embodiments of the present disclosure described herein relate to an electronic device, and more particularly, relate to an electronic device including a pixel.

Multimedia electronic devices such as televisions, mobile phones, tablet computers, navigation systems, and game consoles generate images and display the generated images to users through display screens.

The electronic device includes a plurality of pixels and driving circuits that control an image to be displayed on the plurality of pixels. Each of the plurality of pixels includes a light emitting element and transistors that control the light emitting element.

### SUMMARY

Embodiments of the present disclosure provide a pixel having improved display quality and an electronic device including the same.

According to an embodiment of the present disclosure, a pixel of an electronic device includes a light emitting element connected between a first voltage line and a first node, a first transistor including a first electrode connected to a second node, a second electrode connected to a third node, a gate electrode connected to a fourth node, and a bottom gate electrode for receiving a back gate voltage, a second transistor connected between the first voltage line and the first node, a third transistor connected between the first node and the second node, a fourth transistor connected between the second node and the fourth node, a fifth transistor connected between a fifth node and a first data line for transferring a first data signal, a sixth transistor connected between the third node and a second data line for transferring a second data signal, a seventh transistor connected between the third node and a second voltage line, an eighth transistor connected between the fifth node and the second voltage line, a first capacitor connected between the fourth node and the fifth node, and a second capacitor connected between the third node and the fifth node.

According to an embodiment, during a first period, a first driving voltage supplied through the first voltage line may be transferred to the fourth node through the second, third and fourth transistors, and during the first period, a second driving voltage supplied through the second voltage line may be transferred to the fifth node through the eighth transistor.

According to an embodiment, during a second period subsequent to the first period, the second driving voltage supplied through the second voltage line may be transferred to the second electrode of the first transistor through the seventh transistor.

According to an embodiment, a back gate-source voltage between the bottom gate electrode and the second electrode of the first transistor may have a negative voltage level.

According to an embodiment, during the second period, a threshold voltage of the first transistor may be stored in the first capacitor through the fourth transistor.

According to an embodiment, during a third period subsequent to the second period, the first data signal may be transferred to the gate electrode of the first transistor through the fifth transistor and the first capacitor, and the second data signal may be transferred to the second capacitor through the sixth transistor.

According to an embodiment, when the third period has a duration time of 1 horizontal period, the second period may have a duration time longer than 2 horizontal periods.

According to an embodiment, during a fourth period subsequent to the third period, a current path may be formed between the first voltage line and the second voltage line through the light emitting element, the third transistor, the first transistor, and the seventh transistor.

According to an embodiment, the first transistor may be an N-type transistor using an oxide semiconductor as a semiconductor layer.

According to an embodiment, each of the second, fourth, fifth, sixth, and eighth transistors may include a gate electrode.

According to an embodiment, the gate electrode of each of the second, fourth, and eighth transistors may receive a first scan signal, and the gate electrode of each of the fifth and sixth transistors may receive a second scan signal.

According to an embodiment, the third transistor may include a gate electrode for receiving a first emission signal, and the seventh transistor may include a gate electrode for receiving a second emission signal.

According to an embodiment of the present disclosure, an electronic device includes a display panel including a pixel, and a data driving circuit for providing a first data signal and a second data signal to the pixel. The pixel includes a light emitting element connected between a first voltage line and a first node, a first transistor including a first electrode connected to a second node, a second electrode connected to a third node, a gate electrode connected to a fourth node, and a bottom gate electrode for receiving a back gate voltage, a second transistor connected between the first voltage line and the first node, a third transistor connected between the first node and the second node, a fourth transistor connected between the second node and the fourth node, a fifth transistor connected between a fifth node and a first data line for transferring the first data signal, a sixth transistor connected between the third node and a second data line for transferring the second data signal, a seventh transistor connected between the third node and a second voltage line, an eighth transistor connected between the fifth node and the second voltage line, a first capacitor connected between the fourth node and the fifth node, and a second capacitor connected between the third node and the fifth node.

According to an embodiment, the first transistor may be an N-type transistor using an oxide semiconductor as a semiconductor layer.

According to an embodiment, each of the second, fourth, fifth, sixth, and eighth transistors may include a gate electrode.

According to an embodiment, the electronic device may further include a scan driving circuit, which provides a first scan signal and a second scan signal to the pixel, and a light emission driving circuit, which provides a first emission signal and a second emission signal to the pixel.

According to an embodiment, the gate electrode of each of the second, fourth, and eighth transistors may receive the first scan signal, and the gate electrode of each of the fifth and sixth transistors may receive the second scan signal.

According to an embodiment, during a first period and a second period subsequent to the first period, the first scan signal may be at an active level, and during a third period subsequent to the second period, the second scan signal may be at the active level.

According to an embodiment, the third transistor may include a gate electrode for receiving the first emission signal, the seventh transistor may include a gate electrode for receiving the second emission signal, during the first period and a fourth period subsequent to the third period, the first emission signal may be at the active level, and during the second period and the fourth period, the second emission signal may be at the active level.

According to an embodiment, when the third period has a duration time of 1 horizontal period, the second period may have a duration time longer than 1 horizontal period.

### BRIEF DESCRIPTION OF THE FIGURES

The above and other aspects and features of the present disclosure will become apparent by describing in detail embodiments thereof with reference to the accompanying drawings.

FIG. 1 is a perspective view of an electronic device, according to an embodiment of the present disclosure.

FIG. 2 is a block diagram of a display module, according to an embodiment of the present disclosure.

FIG. 3 is a circuit diagram of a pixel, according to an embodiment of the present disclosure.

FIG. 4 is a timing diagram for describing an operation of a pixel, according to an embodiment of the present disclosure.

FIGS. 5A to 5D are circuit diagrams for describing an operation of a pixel, according to an embodiment of the present disclosure.

FIG. 6A is a graph illustrating characteristics of a transistor including a single gate electrode.

FIG. 6B is a graph illustrating characteristics of a transistor including a double gate electrode.

FIG. 7 is a graph illustrating characteristics of a first transistor according to a back gate-source voltage of a first transistor.

FIG. 8 is a block diagram of an electronic device according to an embodiment.

FIG. 9 is a schematic diagram of electronic devices according to various embodiments

### DETAILED DESCRIPTION

In the specification, when one component (or area, layer, part, or the like) is referred to as being “on”, “connected to”, or “coupled to” another component, it should be understood that the former may be directly on, connected to, or coupled to the latter, and also may be on, connected to, or coupled to the latter via a third intervening component.

Identical drawing symbols refer to identical components. Also, in drawings, the thickness, ratio, and dimension of components are exaggerated for effectiveness of description of technical contents. The term “and/or” includes one or more combinations of the associated listed items.

The terms “first”, “second”, etc. are used to describe various components, but the components are not limited by the terms. The terms are used only to differentiate one component from another component. For example, a first component may be named as a second component, and vice versa, without departing from the spirit or scope of the present disclosure. A singular form, unless otherwise stated, includes a plural form.

Also, the terms “under”, “beneath”, “on”, “above” are used to describe a relationship between components illustrated in a drawing. The terms are relative and are described with reference to a direction indicated in the drawing.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in this specification have the same meaning as commonly understood by those skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the present disclosure will be described with reference to accompanying drawings.

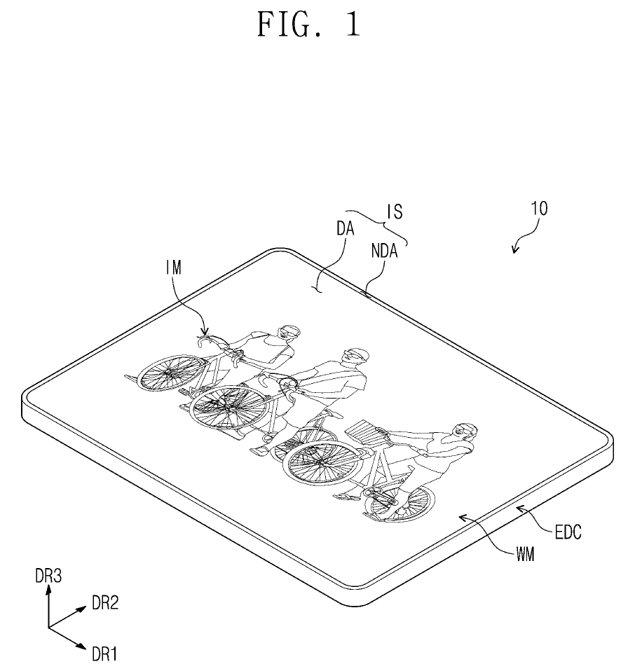

FIG. 1 is a perspective view of an electronic device 10, according to an embodiment of the present disclosure.

Referring to FIG. 1, the electronic device 10 may be activated, in response to an electrical signal. The electronic device 10 according to the present disclosure may be a large-sized electronic device, such as a television, a monitor, etc., as well as a small and medium-sized electronic device, such as a mobile phone, a tablet PC, a notebook computer, a vehicle navigation system, a game console, etc. These are provided only as examples, and it is obvious that the electronic device 10 may include other forms of electronic devices without departing from the concept of the present disclosure. The electronic device 10 has a rectangular shape having a long side in a first direction DR1 and a short side in a second direction DR2 intersecting the first direction DR1. However, a shape of the electronic device 10 is not limited thereto, and the electronic devices 10 having various shapes may be provided. The electronic device 10 may display an image IM toward a third direction DR3, on a display surface IS parallel to each of the first direction DR1 and the second direction DR2.

According to an embodiment, a front surface (or top surface) and a rear surface (or a bottom surface) of each of members are defined based on a direction that the image IM is displayed. The front surface and the rear surface may be opposite to each other in the third direction DR3, and a normal direction of each of the front surface and the rear surface may be parallel to the third direction DR3.

The distance between the front surface and the rear surface in the third direction DR3 may correspond to a thickness of the electronic device 10 in the third direction DR3. Meanwhile, directions that the first, second, and third directions DR1, DR2, and DR3 indicate may be a relative concept and may be changed to different directions.

The electronic device 10 may sense an external input applied from the outside. The external input may include various types of inputs provided from the outside of the electronic device 10. According to an embodiment of the present disclosure, the electronic device 10 may sense a user external input, which is applied from the outside. The user external input may be any one or a combination of various types of external inputs, such as a part of the user’s body, light, heat, gaze, or pressure. In addition, the electronic device 10 may sense the user external input, which is applied to the side surface or the rear surface of the electronic device 10 depending on a structure of the electronic device 10, and is not limited to any one embodiment. As an example of the present disclosure, the external input may include an input by an input device (e.g., a stylus pen, an active pen, a touch pen, an electronic pen, an e-pen, etc.).

The display surface IS of the electronic device 10 may be divided into a display area DA and a non-display area NDA. The display area DA may be an area in which the image IM is displayed. A user visually perceives the image IM through the display area DA. In this embodiment, the display area DA is illustrated in the shape of a quadrangle whose vertexes are rounded. However, this is illustrated by way of example, and the display area DA may have various shapes, and is not limited to any one embodiment.

The non-display area NDA is adjacent to the display area DA. The non-display area NDA may have a given color. The non-display area NDA may surround the display area DA. Accordingly, the shape of the display area DA may actually be defined by the non-display area NDA. However, this is illustrated by way of example, and the non-display area NDA may be disposed to be adjacent to only one side of the display area DA or may be omitted. According to an embodiment of the present disclosure, the electronic device 10 may include various embodiments, and is not limited to any one embodiment.

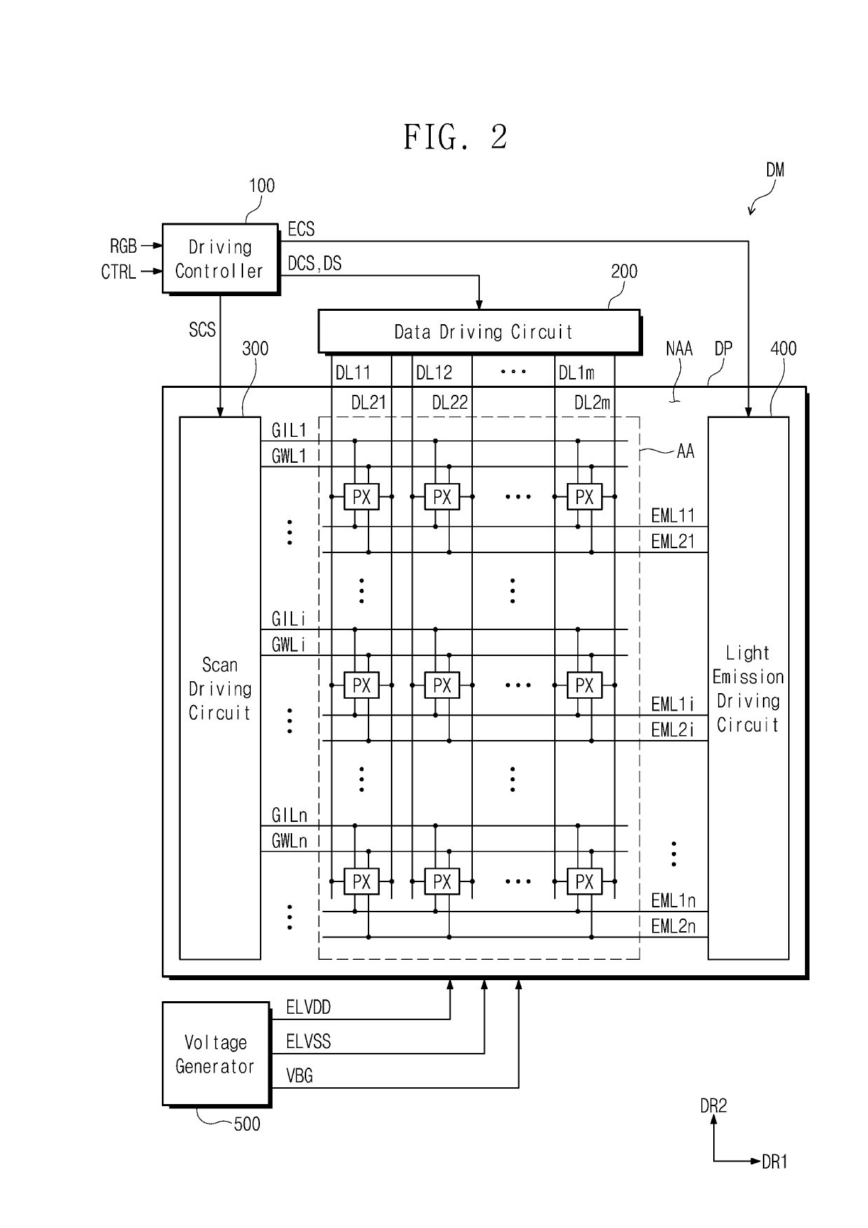

FIG. 2 is a block diagram of a display module DM, according to an embodiment of the present disclosure.

Referring to FIG. 2, the display module DM includes a display panel DP, a driving controller 100, a data driving circuit 200, a scan driving circuit 300, a light emission driving circuit 400, and a voltage generator 500.

The driving controller 100 receives an image signal RGB and a control signal CTRL. In an embodiment, the electronic device 10 illustrated in FIG. 1 further includes a processor, and the image signal RGB and the control signal CTRL may be provided from a processor (e.g., a central processing unit CPU, a graphics processor, or an application processor).

The driving controller 100 converts the image signal RGB into an image data signal DS so as to be output. The driving controller 100 outputs a scan control signal SCS, a data control signal DCS, and an emission control signal ECS.

The data driving circuit 200 receives the data control signal DCS and the image data signal DS from the driving controller 100. The data driving circuit 200 converts the image data signal DS into data signals and then outputs the data signals to a plurality of first data lines DL11 to DL1m and a plurality of second data lines DL21 to DL2m to be described later.

The scan driving circuit 300 receives the scan control signal SCS from the driving controller 100. The scan driving circuit 300 may output scan signals to first scan lines GIL1 to GILn and second scan lines GWL1 to GWLn in response to the scan control signal SCS.

The light emission driving circuit 400 receives the emission control signal ECS from the driving controller 100. The light emission driving circuit 400 may output emission signals to first emission lines EML11 to EML1n and second emission lines EML21 to EML2n in response to the emission control signal ECS.

The voltage generator 500 generates voltages for an operation of the display panel DP. In an embodiment, the voltage generator 500 may generate a first driving voltage ELVDD, a second driving voltage ELVSS, and a back gate voltage VBG for an operation of the display panel DP.

According to an embodiment of the present disclosure, the display panel DP may be a light emitting display panel. For example, the display panel DP may be an organic light emitting display panel, an inorganic light emitting display panel, or an quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot, a quantum rod, etc. The following description will be made that the display panel DP is an organic light emitting display panel, according to the present embodiment.

The display panel DP includes the first scan lines GIL1 to GILn, the second scan lines GWL1 to GWLn, the first emission lines EML11 to EML1n, the second emission lines EML21 to EML2n, the first data lines DL11 to DL1m, and the second data lines DL21 to DL2m, and pixels PX.

The display panel DP includes an active area AA and a non-active area NAA. In an embodiment, the pixels PX may be arranged in the active area AA of the display panel DP, and the scan driving circuit 300 and the light emission driving circuit 400 may be arranged in the non-active area NAA of the display panel DP. In an embodiment, the active area AA and the non-active area NAA may correspond to the display area DA and the non-display area NDA of the electronic device 10 illustrated in FIG. 1, respectively.

In an embodiment, the scan driving circuit 300 is arranged adjacent to a first side of the active area AA. The first scan lines GIL1 to GILn and the second scan lines GWL1 to GWLn extend from the scan driving circuit 300 in the first direction DR1. The light emission driving circuit 400 is arranged adjacent to a second side of the active area AA. The first emission lines EML11 to EML1n and the second emission lines EML21 to EML2n extend from the light emission driving circuit 400 in the opposite direction of the first direction DR1.

The first scan lines GIL1 to GILn, the second scan lines GWL1 to GWLn, the first emission lines EML11 to EML1n, and the second emission lines EML21 to EML2n are arranged to be spaced apart from each other in the second direction DR2. The first data lines DL11 to DL1m and the second data lines DL21 to DL2m extend from the data driving circuit 200 in the opposite direction of the second direction DR2 and are arranged to be spaced apart from each other in the first direction DR1.

In the example illustrated in FIG. 2, the scan driving circuit 300 and the light emission driving circuit 400 are arranged facing each other with the pixels PX therebetween, but the present disclosure is not limited thereto. For another example, the scan driving circuit 300 and the light emission driving circuit 400 may be arranged to be adjacent to each other in the non-active area NAA of the display panel DP. In an embodiment, the scan driving circuit 300 and the light emission driving circuit 400 may be configured as one circuit.

The plurality of pixels PX may be electrically connected to the first scan lines GIL1 to GILn, the second scan lines GWL1 to GWLn, the first emission lines EML11 to EML1n, the second emission lines EML21 to EML2n, the first data lines DL11 to DL1m, and the second data lines DL21 to DL2m, respectively.

In an embodiment, each of the plurality of pixels PX may be electrically connected to two scan lines and two emission lines. For example, as illustrated in FIG. 2, each of the pixels PX of a first row may be electrically connected to the first scan line GIL1, the second scan line GWL1, the first emission line EML11, and the second emission line EML21. The pixels PX of an i-th row may be electrically connected to the first scan line GILi, the second scan line GWLi, the first emission line EML1i, and the second emission line EML2i. The pixels of an n-th row may be connected to the first scan line GILn, the second scan line GWLn, the first emission line EML1n, and the second emission line EML2n.

In an embodiment, each of the plurality of pixels PX may be electrically connected to two data lines. For example, as illustrated in FIG. 2, each of the pixels PX in a first column may be connected to the first data line DL11 and the second data line DL21. Each of the pixels PX in a second column may be connected to the first data line DL12 and the second data line DL22. Each of the pixels PX in an m-th column may be connected to the first data line DL1m and the second data line DL2m.

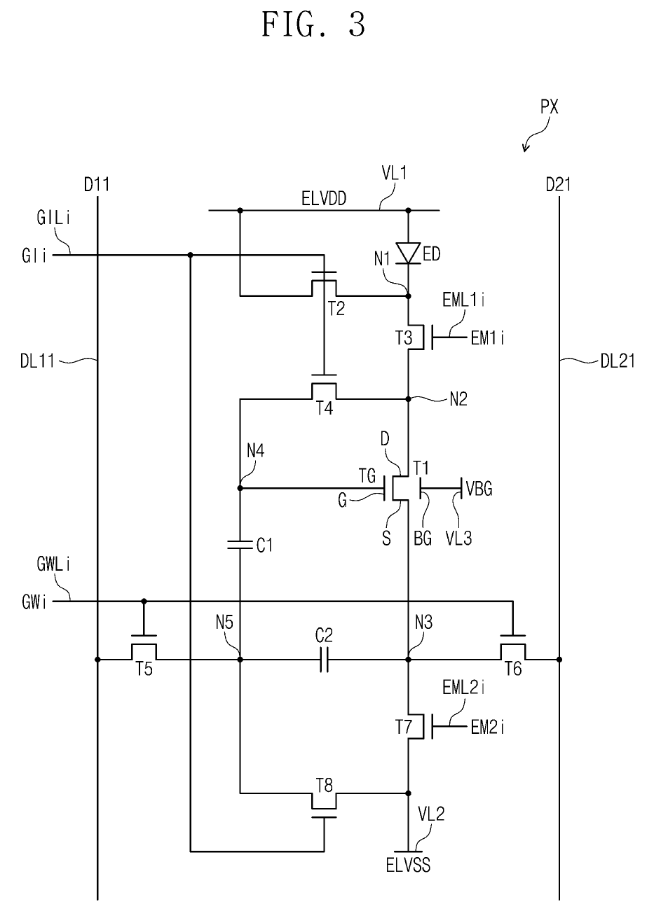

Each of the plurality of pixels PX may include a light emitting element ED (refer to FIG. 3) and a plurality of transistors T1 to T8 (refer to FIG. 3) that control light emission of the light emitting element ED. The scan driving circuit 300 and the light emission driving circuit 400 may include transistors formed through the same process as the plurality of transistors T1 to T8.

FIG. 3 is a circuit diagram of the pixel PX, according to an embodiment of the present disclosure.

FIG. 3 illustrates a circuit diagram of the pixel PX connected to the data line DL11 among the first data lines DL11 to DL1m, the data line DL21 among the second data lines DL21 to DL2m, the first scan line GILi among the first scan lines GIL1 to GILn, the second scan line GWLi among the second scan lines GWL1 to GWLn, the first emission line EML1i among the first emission lines EML11 to EML1n, and the second emission line EML2i among the second emission lines EML21 to EML2n, as illustrated in FIG. 2, by way of example.

Each of the plurality of pixels PX illustrated in FIG. 2 may include the same circuit configuration as the pixel PX illustrated in FIG. 3.

Referring to FIG. 3, the pixel PX of the display module DM (refer to FIG. 2) according to an embodiment includes at least one light emitting element ED, the first to eighth transistors T1, T2, T3, T4, T5, T6, T7, and T8, a first capacitor C1, and a second capacitor C2.

In an embodiment, the light emitting element ED may be a light emitting diode. In this embodiment, an example is described in which one pixel PX includes one light emitting element ED.

In this embodiment, each of the first to eighth transistors T1 to T8 may be an N-type transistor using an oxide semiconductor as a semiconductor layer. However, the present disclosure is not limited thereto, and at least one of the first to eighth transistors T1 to T8 may be a P-type transistor having an LTPS (low-temperature polycrystalline silicon) semiconductor layer in another embodiment. In addition, the circuit configuration of the pixel PX according to the present disclosure is not limited to FIG. 3, and may be modified and implemented.

The first scan line GILi and the second scan line GWLi transfer a first scan signal GIi and a second scan signal GWi provided from the scan driving circuit 300, respectively (refer to FIG. 2).

The first emission line EML1i and the second emission line EML2i may transfer a first emission signal EM1i and a second emission signal EM2i provided from the light emission driving circuit 400 (refer to FIG. 2).

The first data line DL11 and the second data line DL21 transfer the first data signal D11 and a second data signal D21 provided from the data driving circuit 200 (refer to FIG. 2), respectively. Each of the first data signal D11 and the second data signal D21 may have a voltage level corresponding to an image to be displayed on the pixel PX among image signals RGB input to the display module DM (refer to FIG. 1). First to third voltage lines VL1, VL2, and VL3 may transfer the first driving voltage ELVDD, the second driving voltage ELVSS, and the back gate voltage VBG.

The light emitting element ED is connected between the first voltage line VL1 and a first node N1. That is, the anode of the light emitting element ED is connected to the first voltage line VL1, and the cathode of the light emitting element ED is connected to the first node N1.

The first transistor T1 includes a first electrode D, a second electrode S, a gate electrode G, and a bottom gate electrode BG. The bottom gate electrode BG may be referred to as a body electrode or a back gate electrode. The first transistor T1 may be referred to as a driving transistor.

The first electrode D of the first transistor T1 may be connected to a second node N2, the second electrode S may be connected to a third node N3, the gate electrode G may be connected to a fourth node N4, and the bottom gate electrode BG may be connected to the third voltage line VL3.

The second transistor T2 is connected between the first node N1 and the first voltage line VL1, and includes a gate electrode connected to the first scan line GILi.

The third transistor T3 is connected between the first node N1 and the second node N2, and includes a gate electrode connected to the first emission line EML1i.

The fourth transistor T4 is connected between the second node N2 and the fourth node N4, and includes a gate electrode connected to the first scan line GILi.

The fifth transistor T5 is connected between the first data line DL11 and a fifth node N5, and includes a gate electrode connected to the second scan line GWLi.

The sixth transistor T6 is connected between the second data line DL21 and the third node N3, and includes a gate electrode connected to the second scan line GWLi.

The seventh transistor T7 is connected between the third node N3 and the second voltage line VL2, and includes a gate electrode connected to the second emission line EML2i.

The eighth transistor T8 is connected between the fifth node N5 and the second voltage line VL2, and includes a gate electrode connected to the first scan line GILi.

The first capacitor C1 is connected between the fourth node N4 and the fifth node N5. In detail, a first electrode of the first capacitor C1 is connected to the fourth node N4, and a second electrode of the first capacitor C1 is connected to the fifth node N5.

The second capacitor C2 is connected between the fifth node N5 and the third node N3. In detail, a first electrode of the second capacitor C2 is connected to the fifth node N5, and a second electrode of the second capacitor C2 is connected to the third node N3.

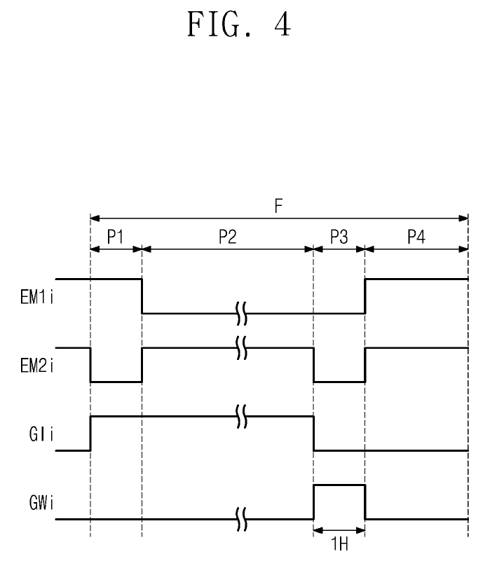

FIG. 4 is a timing diagram for describing an operation of the pixel PX, according to an embodiment of the present disclosure.

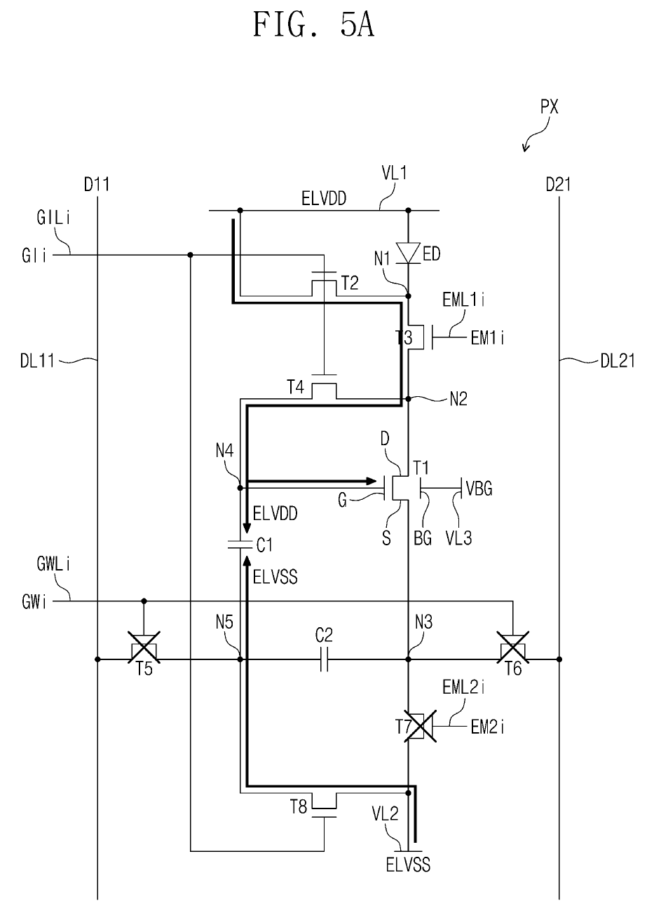

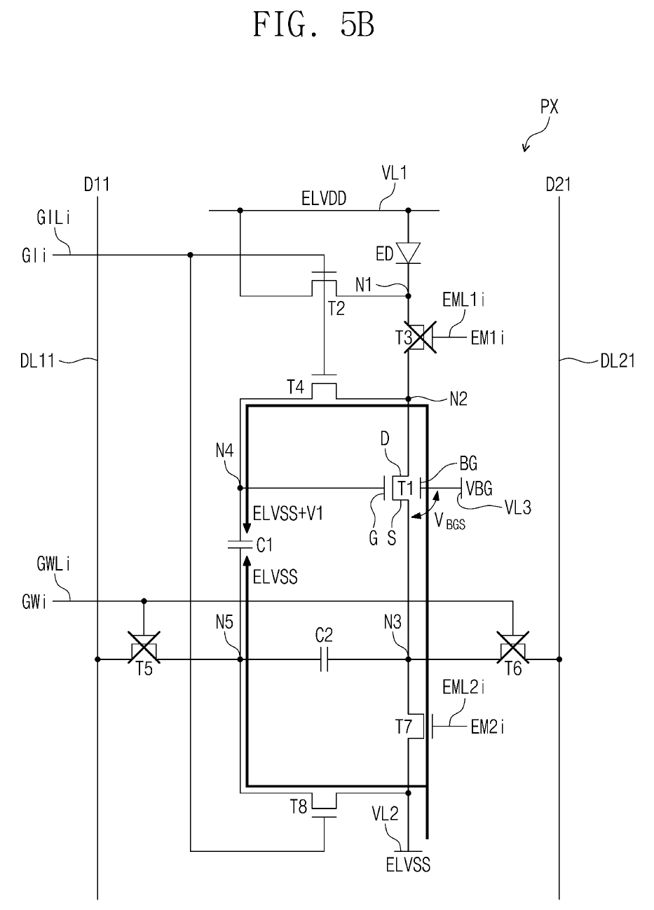

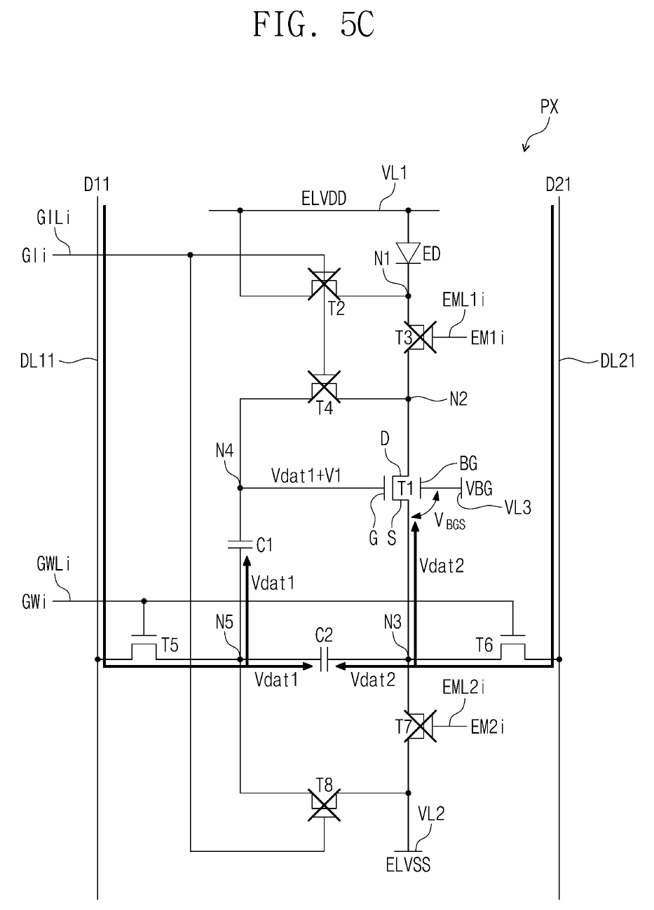

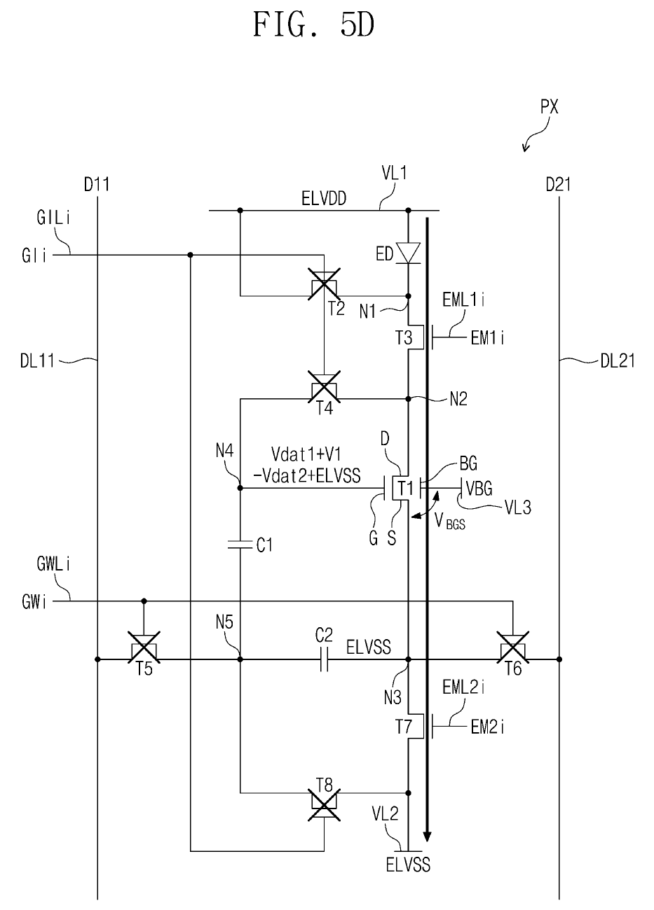

FIGS. 5A to 5D are circuit diagrams for describing the operation of the pixel PX according to an embodiment of the present disclosure.

Referring to FIGS. 4 and 5A, one frame “F” includes first to fourth periods P1, P2, P3, and P4. The first to fourth periods P1, P2, P3, and P4 may be referred to as an initialization period, a threshold voltage extraction period, a data input period, and an emission period, respectively.

During the first period P1, each of the first emission signal EM1i and the first scan signal GIi is at an active level (e.g., a high level), and each of the second emission signal EM2i and the second scan signal GWi is at an inactive level (e.g., a low level).

While the first emission signal EM1i and the first scan signal GIi are at a high level, the second, third, fourth, and eighth transistors T2, T3, T4, and T8 are turned on.

Therefore, during the first period P1, the first driving voltage ELVDD is transferred to the fourth node N4 to which the first electrode of the first capacitor C1 and the gate electrode G of the first transistor T1 are commonly connected through the second, third, and fourth transistors T2, T3, and T4. In addition, during the first period P1, the second driving voltage ELVSS is transferred to the second electrode of the first capacitor C1 through the eighth transistor T8.

As the first driving voltage ELVDD is provided to the gate electrode G of the first transistor T1 in the first period P1, the first transistor T1 may be turned on. However, since the seventh transistor T7 is in a turn-off state, a through current does not flow between the first voltage line VL1 and the second voltage line VL2.

The first period P1 may be a period in which the gate electrode G of the first transistor T1 is initialized to the first driving voltage ELVDD.

Referring to FIG. 4 and FIG. 5B, during the second period P2, the second emission signal EM2i and the first scan signal GIi are at an active level (e.g., a high level), and the first emission signal EM1i and the second scan signal GWi are at an inactive level (e.g., a low level).

While the second emission signal EM2i and the first scan signal GIi are at a high level, the second, fourth, seventh, and eighth transistors T2, T4, T7, and T8 are turned on.

In the first period P1, the first transistor T1 is in the turned on state as the first driving voltage ELVDD is provided to the gate electrode G of the first transistor T1.

The back gate voltage VBG provided to the bottom gate electrode BG of the first transistor T1 may be set such that a back gate-source voltage V_{BGS} of the first transistor T1 has a negative voltage level (or a minus voltage level). Here, the back gate-source voltage V_{BGS} of the first transistor T1 may be a voltage between the gate electrode G and the source electrode S of the first transistor T1.

Since the back gate-source voltage V_{BGS} of the first transistor T1 has a negative voltage level, the first transistor T1 may operate in an enhancement mode.

Since the second driving voltage ELVSS is transferred to the source electrode S of the first transistor T1 through the seventh transistor T7 in the second period P2, the back gate-source voltage V_{BGS} of the first transistor T1 in the second period P2 is ‘VBG-ELVSS’.

In the second period P2, the voltage of the first electrode of the first capacitor C1 has a voltage level that is the second driving voltage ELVSS plus a first voltage V1. In this case, the first voltage V1 may be a threshold voltage V_{T} of the first transistor T1 when the back gate-source voltage V_{BGS} of the first transistor T1 is ‘V_{BGS}-ELVSS’. That is, during the second period P2, the threshold voltage V_{T} of the first transistor T1 is stored in the first capacitor C1 through the fourth transistor T4.

In addition, during the second period P2, the second driving voltage ELVSS is transferred to the second electrode of the first capacitor C1 through the eighth transistor T8. Therefore, a voltage difference between the first electrode and the second electrode of the first capacitor C1 may be the first voltage V1.

The second period P2 may be the threshold extraction period for extracting the threshold voltage V_{T} of the first transistor T1.

Referring to FIG. 4 and FIG. 5C, during the third period P3, the second scan signal GWi is at an active level (e.g., a high level), and the first emission signal EM1i, the second emission signal EM2i, and the first scan signal GIi are at an inactive level (e.g., a low level).

Since the first scan signal GIi is at an inactive level, the fourth transistor T4 is turned off. As the fourth transistor T4 is turned off, the gate electrode G of the first transistor T1 becomes floating.

While the second scan signal GWi is at a high level, the fifth and sixth transistors T5 and T6 are turned on.

A first data voltage Vdat1 of the first data signal D11 supplied through the first data line DL11 is transferred to the second electrode of the first capacitor C1 and the first electrode of the second capacitor C2.

The first data voltage Vdat1 transferred to the first capacitor C1 while the gate electrode G of the first transistor T1 is in a floating state is transferred to the gate electrode G of the first transistor T1.

A second data voltage Vdat2 of the second data signal D21 supplied through the second data line DL21 is transferred to the second electrode of the second capacitor C2 and the source electrode S of the first transistor T1. In this case, the back gate-source voltage V_{BGS} of the first transistor T1 is ‘VBG-Vdat2’.

The third period P3 may be the data input period in which the first data signal D11 is transferred to the gate electrode G of the first transistor T1 and the second data signal D21 is transferred to the source electrode S of the first transistor T1.

Referring to FIG. 4 and FIG. 5D, during the fourth period P4, the first emission signal EM1i and the second emission signal EM2i are at an active level (e.g., a high level), and the first scan signal GIi and the second scan signal GWi are at an inactive level (e.g., a low level).

Since the first scan signal GIi and the second scan signal GWi are at an inactive level, the fifth and eighth transistors T5 and T8 are turned off, so that the first and second capacitors C1 and C2 may be connected in series.

When the first scan signal GIi and the second scan signal GWi transition to an inactive level, the voltage between the gate electrode G and the source electrode S of the first transistor T1, i.e., the gate-source voltage (referred to as V_{GS}), may be ‘Vdat1+V1-Vdat2’.

In this case, when the second emission signal EM2i transitions from an inactive level to an active level, the seventh transistor T7 is turned on. As the seventh transistor T7 is turned on, the second driving voltage ELVSS is transferred to the second node N2.

When the voltage of the second node N2 is changed to the second driving voltage ELVSS, the voltage of the gate electrode G of the first transistor T1 is changed to ‘Vdat1+V1-Vdat2+ELVSS’ through the first and second capacitors C1 and C2.

Since both the first emission signal EM1i and the second emission signal EM2i are at an active level, the third and seventh transistors T3 and T7 are turned on, so that a current flows between the first voltage line VL1 and the second voltage line VL2, and the light emitting element ED emits light.

In this case, since the current corresponding to the gate-source voltage V_{GS} of the first transistor T1, i.e., ‘Vdat1+V1-Vdat2+ELVSS-ELVSS-V1’, flows through the first transistor T1, the light emitting element ED may emit light with a brightness corresponding to ‘Vdat1-Vdat2’.

The fourth period P4 may be the light emitting period in which the light emitting element ED emits light depending on the first data signal D11 and the second data signal D21.

In an embodiment, the voltage of the gate electrode G of the first transistor T1 is determined by a combination of the first data voltage Vdat1 of the first data signal D11 and the second data voltage Vdat2 of the second data signal D21. Therefore, the voltage range of the gate electrode G of the first transistor T1 may be expanded compared to using one data signal.

In other words, the data voltage interval for the grayscale representation of the first data signal D11 may be expanded by operating in response to the first data signal D11 and the second data signal D21 compared to the case where the pixel PX operates in response to one data signal, i.e., the first data signal D11. For example, the voltage interval between the voltage level of the first data signal D11 for representing 10 grayscales and the voltage level of the first data signal D11 for representing 100 grayscales may be expanded. As a result, the grayscale precision of the first data signal D11 may be improved, so that the burden on the data driving circuit 200 (refer to FIG. 2) for improving the precision may be reduced.

In an embodiment, when the third period P3 has a duration time of 1 horizontal period 1H, the second period P2 may have a duration time of 2 horizontal periods to several tens of horizontal periods. That is, the second period P2 has a longer duration time than the third period P3.

By sufficiently securing the time of the threshold extraction period, i.e., the second period P2, for extracting the threshold voltage V_{T} of the first transistor T1, the threshold voltage V_{T} deviation of each pixel PX (refer to FIG. 2) may be sufficiently compensated. As a result, the display quality of the image displayed on the electronic device 10 (refer to FIG. 1) may be improved.

As illustrated in FIG. 3, the light emitting element ED of the pixel PX is connected to the first voltage line VL1, and the second capacitor C2 is connected to the second voltage line VL2 in the first period P1, the second period P2, and the fourth period P4. Since the second voltage line VL2 is commonly connected to the pixels PX (refer to FIG. 2), the second voltage line VL2 has a very large area. Since the second capacitor C2 is connected to the second voltage line VL2 having a large area, the gate-source voltage V_{GS} of the first transistor T1 may be stably maintained. In addition, since the first and second capacitors C1 and C2 are not directly connected to the light emitting element ED, the change in the characteristics of the light emitting element ED does not affect the gate-source voltage V_{GS} of the first transistor T1 or the back gate-source voltage V_{BGS} of the first transistor T1, so that the stable operation of the pixel PX may be guaranteed.

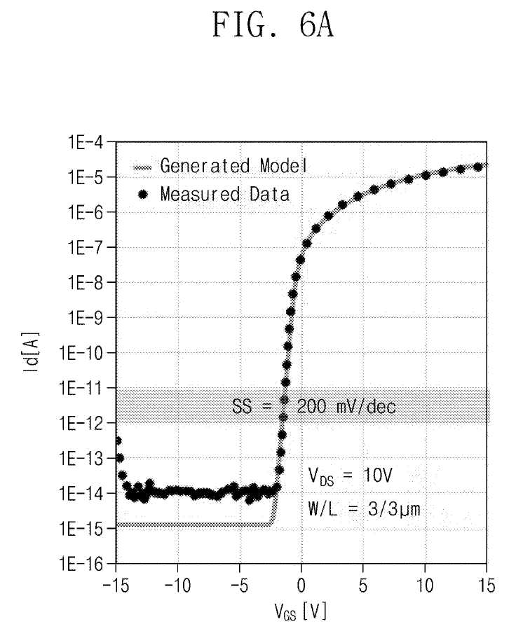

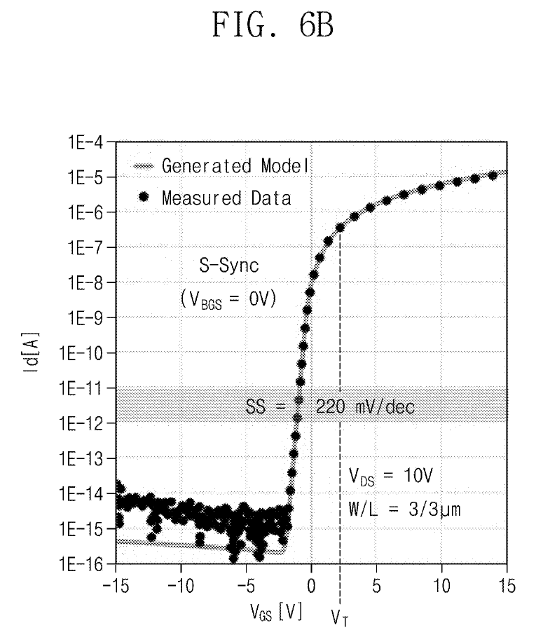

FIG. 6A is a graph illustrating characteristics of a transistor including a single gate electrode.

FIG. 6B is a graph illustrating characteristics of a transistor including a double gate electrode.

In FIGS. 6A and 6B, a horizontal axis of each of the graphs represents the gate-source voltage V_{GS} of the first transistor T1, and a unit of the horizontal axis may be “V” (Volt). A vertical axis of each of the graphs represents a drain-source current Id of the first transistor T1, and a unit of the vertical axis may be “A” (Ampere).

In FIGS. 6A and 6B, when the drain-source voltage V_{DS} of the first transistor T1 is 10V and a ratio of the width to length (W/L) of the first transistor T1 is 3/3 (unit of width: micrometer (μm)), characteristics of the gate-source voltage V_{GS} and the drain-source current Id of the first transistor T1 are illustrated by way of example. Here, the drain-source voltage V_{DS} of the first transistor T1 may be a voltage between the drain electrode D and the source electrode S of the first transistor T1, and gate-source voltage V_{GS} of the first transistor T1 may be a voltage between the gate electrode G and the source electrode S of the first transistor T1.

For example, when the first transistor T1 illustrated in FIG. 3 is a transistor that does not include a bottom gate electrode, that is, includes a single gate electrode, the first transistor T1 may have gate-source voltage V_{GS} and the drain-source current Id characteristics as illustrated in FIG. 6A.

As illustrated in FIG. 3, when the first transistor T1 includes a bottom gate electrode, the first transistor T1 may have gate-source voltage V_{GS} and the drain-source current Id characteristics as illustrated in FIG. 6B.

A subthreshold swing SS of the first transistor T1, which is an N-type transistor having an oxide semiconductor as a semiconductor layer, may be less than a swing of a P-type transistor having the LTPS semiconductor layer. The subthreshold swing SS of a transistor may be defined as the gate voltage increase amount to increase the current by 10 times. The unit of the subthreshold swing may be millivolts per decade (mV/dec). For example, in the example illustrated in FIG. 6A, the subthreshold swing of the transistor having a single gate electrode may be 200mV/dec.

The subthreshold swing SS of the first transistor T1 having a double gate electrode may be 220mV/dec.

When the back gate-source voltage V_{BGS} of the first transistor T1 is 0V, the threshold voltage V_{T} of the first transistor T1 may have a positive value adjacent to 0V.

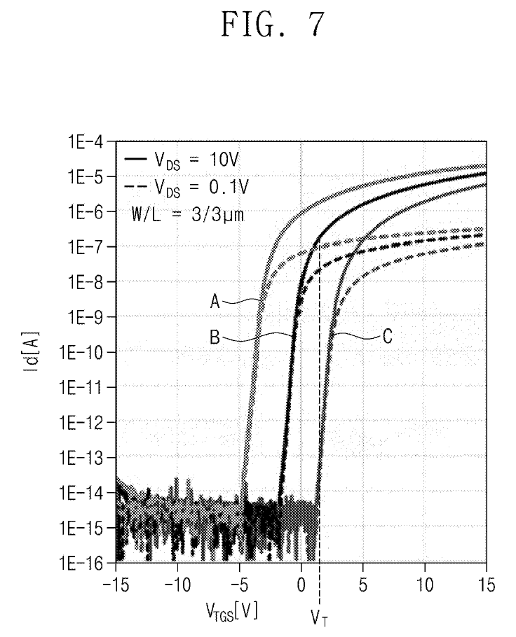

FIG. 7 is a graph illustrating characteristics of the first transistor T1 according to the back gate-source voltage V_{BGS} of the first transistor T1.

In FIG. 7, a horizontal axis of the graph represents the gate-source voltage V_{GS} of the first transistor T1, and a unit of the horizontal axis may be “V” (Volt). A vertical axis of the graph represents the drain-source current Id of the first transistor T1, and a unit of the vertical axis may be “A” (Ampere).

FIG. 7 illustrates, by way of example, characteristics of the gate-source voltage V_{GS} and the drain-source current Id of the first transistor T1 according to the back gate-source voltage V_{BGS} of the first transistor T1 whose width-to-length ratio W/L is 3/3 (unit of width: micrometer (μm)).

In FIG. 7, a solid line represents the gate-source voltage V_{GS} and the drain-source current Id characteristics of the first transistor T1 when the drain-source voltage V_{DS} of the first transistor T1 is 10V, and a dotted line represents the gate-source voltage V_{GS} and the drain-source current Id characteristics of the first transistor T1 when the drain-source voltage V_{DS} of the first transistor T1 is 0.1V.

In FIG. 7, “A”, “B”, and “C” represent characteristics of the gate-source voltage V_{GS} and the drain-source current Id of the first transistor T1 when the back gate-source voltage V_{BGS} of the first transistor T1 is +5V, 0V, and -5V, respectively.

When the back gate-source voltage V_{BGS} of the first transistor T1 increases from 0V to +5V, a curve representing the characteristics of the gate-source voltage V_{GS} and the drain-source current Id of the first transistor T1 shifts to the left from “B” to “A”.

When the back gate-source voltage V_{BGS} of the first transistor T1 decreases from 0V to -5V (i.e., when the back gate-source voltage V_{BGS} has a negative voltage level), the curve representing the characteristics of the gate-source voltage V_{GS} and the drain-source current Id of the first transistor T1 shifts to the right from “B” to “C”. In this case, the first transistor T1 may stably operate in the enhancement mode. Therefore, during the second period P2 (refer to FIG. 4), the threshold voltage V_{T} of the first transistor T1 may be stably extracted and stored in the first capacitor C1.

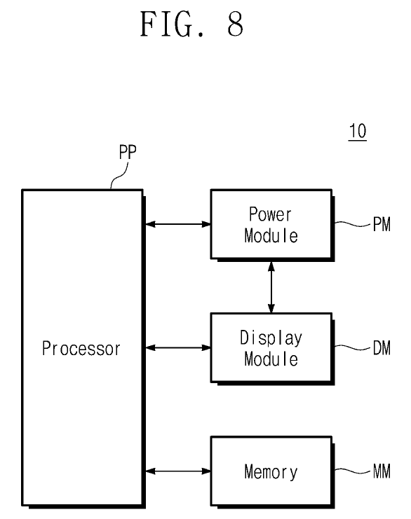

FIG. 8 is a block diagram of the electronic device 10 according to an embodiment.

Referring to FIG. 8, the electronic device 10 according to an embodiment may include the display module DM, a processor PP, a memory MM, and a power module PM.

The processor PP may include at least one of a central processing unit (CPU), an application processor (AP), a graphics processing unit (GPU), a communication processor (CP), an image signal processor (ISP), and a controller.

The memory MM may store data information for operations of the processor PP or the display module DM. When the processor PP executes an application stored in the memory MM, an image data signal and/or an input control signal is transferred to the display module DM, and the display module DM may process the received signal and may output image information through a display screen.

In an embodiment, the display module DM may include the components illustrated in FIG. 2. The display module DM may operate in response to the image signal RGB and the control signal CTRL provided from the processor PP.

The power module PM may include a power supply module, such as a power adapter or a battery device, and a power conversion module that converts power supplied by the power supply module to generate power for the operation of the electronic device 10.

In an embodiment, the voltage generator 500 illustrated in FIG. 2 may be operated by power provided from the power module PM. In an embodiment, the power module PM may include the voltage generator 500 illustrated in FIG. 2.

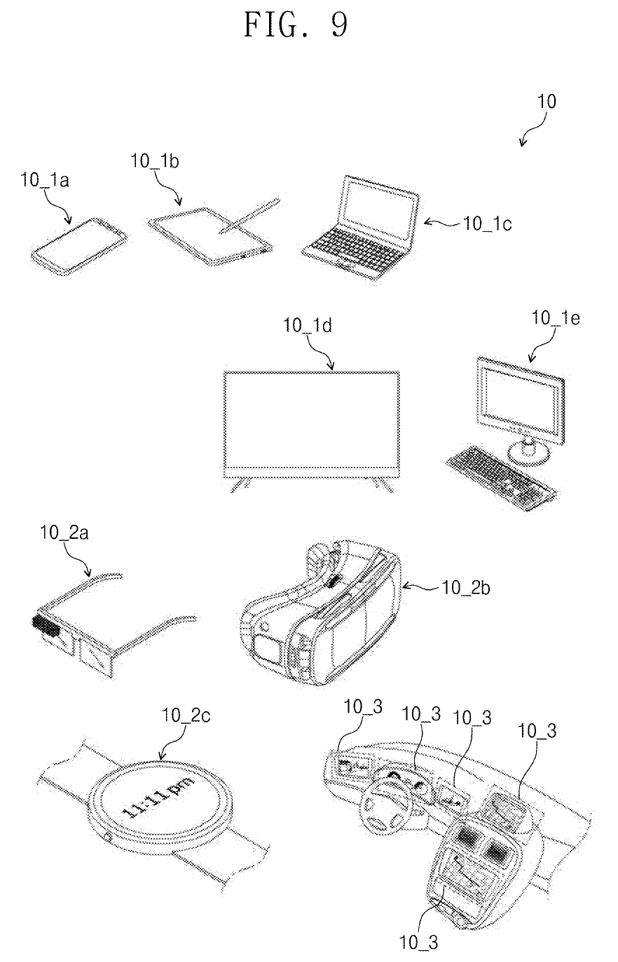

FIG. 9 is a schematic diagram of electronic devices according to various embodiments.

Referring to FIG. 9, various electronic devices according to embodiments may include not only image display electronic devices such as a smart phone 10_1a, a tablet PC 10_1b, a laptop computer 10_1c, a TV 10_1d, a desk monitor 10_1e, but also wearable electronic devices including display modules such as smart glasses 10_2a, a head-mounted display 10_2b, a smart watch 10_2c, etc., and vehicle electronic devices 10_3 including display modules such as a Center Information Display (“CID”) placed on an instrument panel, a center fascia, or a dashboard of a vehicle, a room mirror display, etc.

According to an embodiment of the present disclosure, the pixel having such a configuration allows the driving transistor to operate in a stable enhancement mode by always maintaining the back gate voltage of the driving transistor at a negative voltage level. Since the driving transistor may operate in the stable enhancement mode, the threshold voltage may be extracted through the diode connection structure of the driving transistor. In this case, since sufficient time for extracting the threshold voltage may be secured, a favorable effect may be obtained in compensating for the threshold voltage deviation between pixels. Therefore, the display quality of the image displayed on the electronic device may be improved.

One pixel may represent a grayscale by a current corresponding to a combination of two data signals. Therefore, the voltage range of the data signal for the grayscale representation may be expanded. As a result, the burden of increased costs for improving the precision of the data driving circuit in the electronic device may be reduced.

Although the present disclosure has been described above with reference to embodiments thereof, it will be understood by those skilled in the art or having ordinary knowledge in the art that various modifications, and substitutions are possible, without departing from the spirit and the technical scope of the present disclosure as set forth in the claims below. Accordingly, the technical scope of the present disclosure is not limited to the detailed description of this specification, but should be defined by the claims.

What is claimed is:

1. A pixel comprising:
a light emitting element connected between a first voltage line and a first node;
a first transistor including a first electrode connected to a second node, a second electrode connected to a third node, a gate electrode connected to a fourth node, and a bottom gate electrode, which receives a back gate voltage;
a second transistor connected between the first voltage line and the first node;
a third transistor connected between the first node and the second node;
a fourth transistor connected between the second node and the fourth node;
a fifth transistor connected between a fifth node and a first data line, which transfers a first data signal;
a sixth transistor connected between the third node and a second data line, which transfers a second data signal;
a seventh transistor connected between the third node and a second voltage line;
an eighth transistor connected between the fifth node and the second voltage line;
a first capacitor connected between the fourth node and the fifth node; and
a second capacitor connected between the third node and the fifth node.

2. The pixel of claim 1, wherein during a first period, a first driving voltage supplied through the first voltage line is transferred to the fourth node through the second, third and fourth transistors, and
wherein during the first period, a second driving voltage supplied through the second voltage line is transferred to the fifth node through the eighth transistor.

3. The pixel of claim 2, wherein during a second period subsequent to the first period, the second driving voltage supplied through the second voltage line is transferred to the second electrode of the first transistor through the seventh transistor.

4. The pixel of claim 3, wherein a back gate-source voltage between the bottom gate electrode and the second electrode of the first transistor has a negative voltage level.

5. The pixel of claim 4, wherein during the second period, a threshold voltage of the first transistor is stored in the first capacitor through the fourth transistor.

6. The pixel of claim 3, wherein during a third period subsequent to the second period, the first data signal is transferred to the gate electrode of the first transistor through the fifth transistor and the first capacitor, and the second data signal is transferred to the second capacitor through the sixth transistor.

7. The pixel of claim 6, wherein when the third period has a duration time of 1 horizontal period, the second period has a duration time longer than 2 horizontal periods.

8. The pixel of claim 6, wherein during a fourth period subsequent to the third period, a current path is formed between the first voltage line and the second voltage line through the light emitting element, the third transistor, the first transistor, and the seventh transistor.

9. The pixel of claim 1, wherein the first transistor is an N-type transistor using an oxide semiconductor as a semiconductor layer.

10. The pixel of claim 1, wherein each of the second, fourth, fifth, sixth, and eighth transistors includes a gate electrode.

11. The pixel of claim 10, wherein the gate electrode of each of the second, fourth, and eighth transistors receives a first scan signal, and
wherein the gate electrode of each of the fifth and sixth transistors receives a second scan signal.

12. The pixel of claim 11, wherein the third transistor includes a gate electrode, which receives a first emission signal, and
wherein the seventh transistor includes a gate electrode, which receives a second emission signal.

13. An electronic device comprising:
a display panel including a pixel; and
a data driving circuit, which provides a first data signal and a second data signal to the pixel, and
wherein the pixel includes:
a light emitting element connected between a first voltage line and a first node;
a first transistor including a first electrode connected to a second node, a second electrode connected to a third node, a gate electrode connected to a fourth node, and a bottom gate electrode, which receives a back gate voltage;
a second transistor connected between the first voltage line and the first node;
a third transistor connected between the first node and the second node;
a fourth transistor connected between the second node and the fourth node;
a fifth transistor connected between a fifth node and a first data line, which transfers the first data signal;
a sixth transistor connected between the third node and a second data line, which transfers the second data signal;
a seventh transistor connected between the third node and a second voltage line;
an eighth transistor connected between the fifth node and the second voltage line;
a first capacitor connected between the fourth node and the fifth node; and
a second capacitor connected between the third node and the fifth node.

14. The electronic device of claim 13, wherein the first transistor is an N-type transistor using an oxide semiconductor as a semiconductor layer.

15. The electronic device of claim 13, wherein each of the second, fourth, fifth, sixth, and eighth transistors includes a gate electrode.

16. The electronic device of claim 15, further comprising:
a scan driving circuit, which provides a first scan signal and a second scan signal to the pixel; and
a light emission driving circuit, which provides a first emission signal and a second emission signal to the pixel.

17. The electronic device of claim 16, wherein the gate electrode of each of the second, fourth, and eighth transistors receives the first scan signal, and
wherein the gate electrode of each of the fifth and sixth transistors receives the second scan signal.

18. The electronic device of claim 17, wherein during a first period and a second period subsequent to the first period, the first scan signal is at an active level, and
wherein during a third period subsequent to the second period, the second scan signal is at the active level.

19. The electronic device of claim 18, wherein the third transistor includes a gate electrode, which receives the first emission signal,
wherein the seventh transistor includes a gate electrode, which receives the second emission signal,
wherein during the first period and a fourth period subsequent to the third period, the first emission signal is at the active level, and
wherein during the second period and the fourth period, the second emission signal is at the active level.

20. The electronic device of claim 19, wherein when the third period has a duration time of 1 horizontal period, the second period has a duration time longer than 1 horizontal period.
